(19) United States
(12) Patent Application Publication
(10) Pub. No.: US 2024/0394434 A1
(43) Pub. Date: Nov. 28, 2024

(54) SIMULATION SYSTEM AND NON-TRANSITORY COMPUTER-READABLE RECORDING MEDIUM

(71) Applicant: TOYOTA JIDOSHA KABUSHIKI KAISHA, Aichi-ken (JP)

(72) Inventors: Takahiro SAKURAI, Nagoya-shi (JP); Masafumi KADOI, Chita-shi (JP); Kensuke MATSUMOTO, Nagoya-shi (JP); Shigefumi TOKUDA, Susono-shi (JP); Yoshio TAKIZAWA, Nagoya-shi (JP); Ambi SHO, Nisshin-shi (JP); Takumi BAN, Tokyo (JP); Hideo HASEGAWA, Nagoya-shi (JP); Kenta MIYAHARA, Tokyo (JP); Shinsuke YAMAUCHI, Toyota-shi (JP)

(21) Appl. No.: 18/656,597

(22) Filed: May 7, 2024

(30) Foreign Application Priority Data
May 22, 2023 (JP) 2023-083867

(51) Int. Cl. G06F 30/20; G06Q 10/0631

(52) U.S. Cl. CPC G06F 30/20; G06Q 10/06316

(57) ABSTRACT

A simulation system simulates a predetermined work in a virtual space. A comment database indicates a correspondence relationship between a comment created by a reference worker regarding the predetermined work and a characteristic of the reference worker. The simulation system acquires information on a model motion that serves as a model when carrying out the predetermined work. The simulation system acquires information on a characteristic of a target worker carrying out the predetermined work. The simulation system extracts the comment associated with the characteristic of the reference worker corresponding to the characteristic of the target worker, based on the comment database. When the target worker carries out the predetermined work in the virtual space, the simulation system draws a model worker performing the model motion in the virtual space and presents the extracted comment to the target worker.

### CROSS-REFERENCES TO RELATED APPLICATION

The present disclosure claims priority to Japanese Patent Application No. 2023-083867, filed on May 22, 2023, the contents of which application are incorporated herein by reference in their entirety.

### TECHNICAL FIELD

The present disclosure relates to a technique for simulating a predetermined work in a virtual space.

### BACKGROUND ART

Patent Literature 1 discloses an information processing apparatus that provides learning contents used for learning body movement. The information processing apparatus displays a superimposed video, in which a teacher digital twin and a student digital twin are superimposed on each other, on a student-side device. In addition, the information processing apparatus displays instruction information on the student-side device based on an evaluation value of the student digital twin.

### LIST OF RELATED ART

Patent Literature 1: International Publication WO 2021/230101

### SUMMARY

When a worker learns a predetermined work, it may be conceivable to present a comment (advice or the like) regarding the predetermined work to the worker. However, tricks and weak points in learning a work may vary from person to person. Presenting a comment that does not match the worker or a comment that is not helpful to the worker cannot produce effects as expected. However, presenting all comments to the worker merely confuses the worker and hinders the worker from knowing which comment is helpful after all.

An object of the present disclosure is to provide a technique capable of improving learning effectiveness and learning efficiency when a worker learns a predetermined work.

An aspect of the present disclosure is directed to a simulation system for simulating a predetermined work in a virtual space.

The simulation system includes:
one or more processors; and
one or more storages storing a comment database.

The comment database indicates a correspondence relationship between a comment created by a reference worker regarding the predetermined work and a characteristic of the reference worker.

The one or more processors acquire information on a model motion that serves as a model when carrying out the predetermined work.

The one or more processors acquire information on a characteristic of a target worker carrying out the predetermined work.

The one or more processors extract the comment associated with the characteristic of the reference worker corresponding to the characteristic of the target worker, based on the comment database.

The one or more processors not only draw a model worker performing the model motion in the virtual space but also present the extracted comment to the target worker, when the target worker carries out the predetermined work in the virtual space.

Another aspect of the present disclosure is directed to a simulation program, executed by a computer, for simulating a predetermined work in a virtual space.

A comment database indicates a correspondence relationship between a comment created by a reference worker regarding the predetermined work and a characteristic of the reference worker.

The simulation program, when executed by a computer, causes the computer to execute:
acquiring information on a model motion that serves as a model when carrying out the predetermined work;
acquiring information on a characteristic of a target worker carrying out the predetermined work;
extracting the comment associated with the characteristic of the reference worker corresponding to the characteristic of the target worker, based on the comment database; and
not only drawing a model worker performing the model motion in the virtual space but also presenting the extracted comment to the target worker, when the target worker carries out the predetermined work in the virtual space.

The simulation program may be recorded on a non-transitory computer-readable recording medium.

According to the present disclosure, the comment database is prepared. The comment database indicates the correspondence relationship between the comment created by the reference worker regarding the predetermined work and the characteristic of the reference worker. Based on the comment database, the comment associated with the characteristic of the reference worker corresponding to the characteristic of the target worker is extracted. Then, the extracted comment is selectively presented to the target worker. Not all the comments are indiscriminately presented to the worker, which does not confuse the target worker. Meanwhile, an appropriate comment matching the characteristic of the target worker is presented to the target worker. That is, the target worker is able to learn the predetermined work with reference to the appropriate comment matching the characteristic of the target worker. Therefore, the learning effectiveness and the learning efficiency of the target worker are improved.

### BRIEF DESCRIPTION OF DRAWINGS

FIG. 1 is a conceptual diagram for explaining an overview of a simulation system according to an embodiment;

FIG. 2 is a block diagram showing an example of a configuration of a simulation system according to an embodiment;

FIG. 3 is a conceptual diagram for explaining an example of a comment database according to an embodiment; and

FIG. 4 is a conceptual diagram for explaining a comment filtering function according to an embodiment.

### DETAILED DESCRIPTION

### 1. Overview of Simulation System

A predetermined work carried out by a worker in a real space is considered. For example, the predetermined work is carried out in an real factory. The predetermined work is, for example, assembly of components. According to the present embodiment, simulation is utilized for efficiently training a worker who is supposed to do the predetermined work.

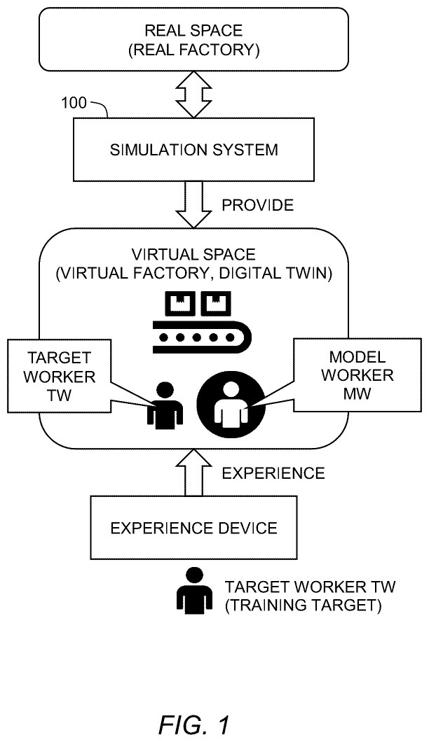

FIG. 1 is a conceptual diagram for explaining an overview of a simulation system 100 according to the present embodiment. The simulation system 100 performs, in a virtual space, a simulation of the predetermined work carried out by a worker. For this purpose, the simulation system 100 virtually reproduces, in the virtual space, a work environment in which the worker carries out the predetermined work. For example, the simulation system 100 reproduces (renders) the work environment in the virtual space based on the DigitalTwin technology. For example, the simulation system 100 reproduces a virtual factory (DigitalTwin plant) simulating a real factory in the virtual space.

A worker being a training target (hereinafter referred to as a “target worker TW”) is able to experience the predetermined work in the virtual space by using an experience device. For example, the experience device is a wearable device such as a head mounted display (HMD) or the like. The head mounted display displays the virtual space reproduced by the simulation system 100. A motion (e.g., a motion of a hand) of the target worker TW in the real space is recognized by a motion capture technology. For example, the motion of the target worker TW is recognized by imaging the target worker TW with a camera. As another example, an inertial sensor (e.g., a gyro sensor, an acceleration sensor, or the like) may be attached to a body of the target worker TW, and the motion of the target worker TW may be recognized based on a result of detection by the inertial sensor. The simulation system 100 draws and superimposes the recognized motion of the target worker TW on the virtual space. For example, the simulation system 100 draws and superimposes the recognized motion of the hand of the target worker TW on the virtual space. As a result, the target worker TW is able to feel as if he or she is doing the predetermined work in the virtual space. That is, the target worker TW is able to experience the predetermined work in the virtual space.

In addition, the simulation system 100 may draw and superimpose a virtual model worker MW performing a model motion on the virtual space. The model motion is a motion serving as a model when the target worker TW carries out the predetermined work. In the virtual space, the virtual model worker MW performs the model motion. The model worker MW may also be referred to as a “ghost worker.” In the virtual space, the target worker TW carries out the predetermined work by imitating the model motion performed by the model worker MW. This enables efficient and effective training.

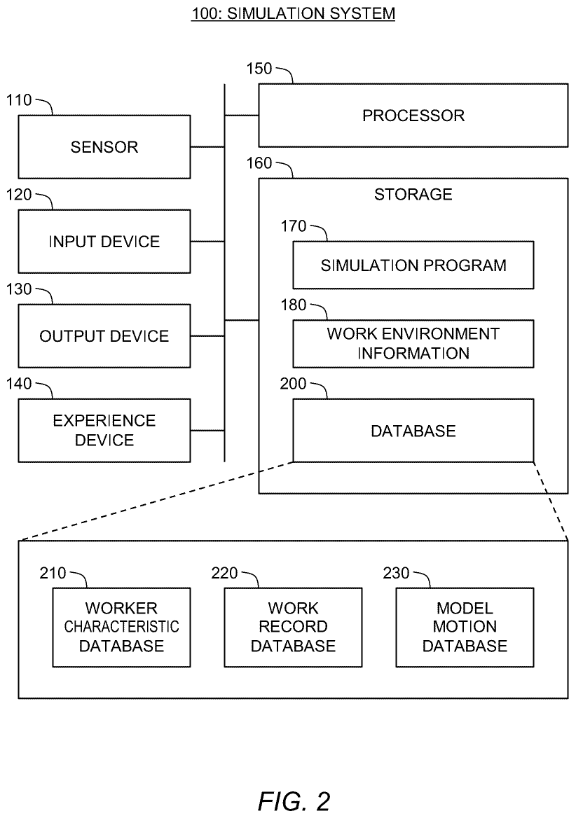

FIG. 2 is a block diagram showing an example of a configuration of the simulation system 100 according to the present embodiment. The simulation system 100 includes a sensor 110, an input device 120, an output device 130, and an experience device 140.

The sensor 110 is set in the real space and detects a variety of information. For example, the sensor 110 detects a motion of a worker in the real space. Examples of the sensor 110 that detects the motion of the worker include a camera, an infrared sensor, an inertial sensor, and the like. For example, the motion of the worker can be detected by capturing an image of the worker with a camera. As another example, the inertial sensor (e.g., a gyro sensor, an acceleration sensor, or the like) may be attached to a body of the worker, and the motion of the worker may be detected by the inertial sensor.

As another example, the sensor 110 may detect a physical characteristic of the worker in the real space. Examples of the physical characteristic include a dominant hand, a hand size, grip strength, a height, a muscle mass, acuity of vision, and the like. For example, the dominant hand of the worker is detected based on the motion of the worker captured by the camera. As another example, the hand size, the height, and the like are detected based on the image of the worker captured by the camera. In addition, the sensor 110 may include a height meter, a weight meter, a body composition meter, a grip strength meter, a vision analyzer, and the like.

As still another example, the sensor 110 may include a biometric sensor that detects biometric information of the worker in the real space. Examples of the biometric information include a body temperature, a heart rate, a level of fatigue, a level of stress, and the like.

Examples of the input device 120 include a touch panel, a keyboard, a mouse, a microphone, and the like. Examples of the output device 130 include a display, a touch panel, a speaker, and the like.

The experience device 140 is used by the target worker TW being the training target for experiencing a work environment and the predetermined work in the virtual space. For example, the experience device 140 is a wearable device such as a head mounted display (HMD) and the like. The head mounted display displays the virtual space reproduced by the simulation system 100.

The simulation system 100 further includes one or more processors 150 (hereinafter simply referred to as a “processor 150” or “processing circuitry”) and one or more storages 160 (hereinafter simply referred to as a “storage 160”). The processor 150 executes a variety of processing. Examples of the processor 150 include a central processing unit (CPU), a graphics processing unit (GPU), an application specific integrated circuit (ASIC), a field-programmable gate array (FPGA), and the like. The storage 160 stores a variety of information. Examples of the storage 160 include a hard disk drive (HDD), a solid state drive (SSD), a volatile memory, a non-volatile memory, and the like.

A simulation program 170 is a computer program for performing the above-described simulation in the virtual space, and is executed by the processor 150. A variety of processing by the simulation system 100 may be implemented by a cooperation of the processor 150 executing the simulation program 170 and the storage 160. The simulation program 170 is stored in the storage 160. The simulation program 170 may be recorded on a non-transitory computer-readable recording medium.

Work environment information 180 is information of a work environment (for example, a real factory) reproduced in the virtual space. For example, the work environment information 180 indicates a three-dimensional configuration of structures (e.g., lines, machines, walls, columns, and the like) in the work environment. For example, the three-dimensional configuration of the structures is expressed by CAD data. The work environment information 180 is stored in the storage 160.

The storage 160 further stores a database 200. The database 200 includes a worker characteristic database 210, a work record database 220, and a model motion database 230.

The worker characteristic database 210 is a database indicating the physical characteristic for each worker. Examples of the physical characteristic include a dominant hand, a hand size, grip strength, a height, a muscle mass, acuity of vision, and the like. For example, the physical characteristic of each worker is detected by the sensor 110 described above. As another example, each worker may input his or her physical characteristic by the use of the input device 120. The physical characteristic represented by numerical values such as the height may be grouped into several groups for each predetermined range.

The work record database 220 is a database indicating past records of the predetermined work that have been carried out by a variety of workers. For example, the work record database 220 includes a video of a worker who is doing the predetermined work. The video of the worker is taken by the camera included in the sensor 110. As another example, the work record database 220 may indicate a content of a motion performed a worker during the predetermined work. As still another example, the work record database 220 may indicate a time required for a worker to complete the predetermined work. Such the work record database 220 is generated based on the motion of the worker detected by the sensor 110.

The model motion database 230 is a database related to the model motion that serves as a model when the target worker TW carries out the predetermined work. The model motion regarding the predetermined work may be generated in advance based on the work record database 220.

The processor 150 reproduces the work environment in which the worker carries out the predetermined work in the virtual space based on the work environment information 180. For example, the processor 150 reproduces (renders) the work environment in the virtual space based on the DigitalTwin technology.

Moreover, the processor 150 uses the sensor 110 to recognize the motion of the target worker TW being the training target. The motion of the target worker TW in the real space is recognized by using the motion capture technology. For example, the motion of the target worker TW is recognized by imaging the target worker TW with the camera. As another example, the inertial sensor may be attached to the body of the target worker TW, and the motion of the target worker TW may be recognized based on a result of detection by the inertial sensor. The processor 150 draws and superimposes the recognized motion of the target worker TW on the virtual space. For example, the processor 150 draws and superimposes the recognized motion of the hand of the target worker TW on the virtual space. Through the experience device 140, the target worker TW is able to feel as if he or she is doing the predetermined work in the virtual space. That is, the target worker TW is able to experience the predetermined work in the virtual space through the experience device 140.

Furthermore, the processor 150 determines, based on the model motion database 230, the model motion that serves as a model when the target worker TW carries out the predetermined work. Then, the processor 150 draws and superimposes the virtual model worker MW performing the model motion on the virtual space. In the virtual space, the target worker TW carries out the predetermined work by imitating the model motion performed by the model worker MW. This enables efficient and effective training.

### 2. Comment Database

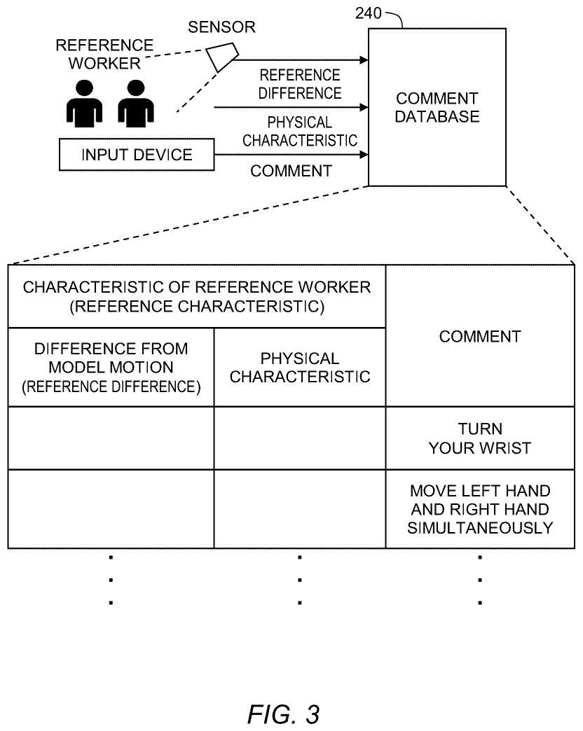

FIG. 3 is a conceptual diagram for explaining an example of a comment database 240 according to the present embodiment. The comment database 240 is a database of comments on the predetermined work, and is stored in the storage 160. Examples of the comment on the predetermined work include advices, tricks, tips, noticed points, and the like. Such the comment is created in advance by a worker (a predecessor) who has done the predetermined work in the past. The worker (predecessor) who has done the predetermined work in the past is hereinafter referred to as a “reference worker.” Each reference worker can input the comment regarding the predetermined work by using the input device 120. The simulation system 100 registers the comments input by each reference worker in the comment database 240.

According to the present embodiment, the comment regarding the predetermined work is associated with a characteristic of the reference worker who creates the comment. The characteristic of the reference worker is hereinafter referred to as a “reference characteristic.” That is, the comment database 240 indicates a correspondence relationship between the reference characteristic of the reference worker and the comment created by the reference worker regarding the predetermined work.

A first example of the reference characteristic is a difference between the model motion and an actual motion of the reference worker when carrying out the predetermined work. The actual motion of the reference worker when carrying out the predetermined work is recognized by the sensor 110 (e.g., the camera). The actual motion of the reference worker when carrying out the predetermined work can also be acquired from the work record database 220. The model motion regarding the predetermined work is acquired from the model motion database 230. The difference between the model motion the actual motion of the reference worker when carrying out the predetermined work is hereinafter referred to as a “reference difference.” For example, the reference difference is an erroneous motion that is not included in the model motion. As another example, the reference difference is a delay time of the actual motion of the reference worker from the model motion. As still another example, the reference difference is a distance between a position of a hand of the model worker MW and a position of a hand of the reference worker. The simulation system 100 acquires information on the reference difference, and registers a correspondence relationship between the reference difference and the comment in the comment database 240.

A second example of the reference characteristic is the physical characteristic (e.g., a dominant hand, a hand size, a height, and the like) of the reference worker. The physical characteristic of the reference worker is obtained from the worker characteristic database 210. The simulation system 100 acquires information on the physical characteristic of the reference worker and registers a correspondence relationship between the physical characteristic and the comment in the comment database 240.

### 3. Comment Filtering Function

As described above, when the target worker TW carries out the predetermined work in the virtual space, the simulation system 100 draws the model worker MW performing the model motion in the virtual space. At the same time, the simulation system 100 may acquire the comment regarding the predetermined work from the comment database 240 and present the acquired comment to the target worker TW. For example, the simulation system 100 draws the comment near the model worker MW in the virtual space. As another example, the simulation system 100 may draw the comment in a balloon coming out from the model worker MW in the virtual space. As still another example, the simulation system 100 may output a voice comment from a speaker.

However, tricks and weak points in learning a work may vary from person to person. Presenting a comment that does not match the target worker TW or a comment that is not helpful to the target worker TW cannot produce effects as expected. For example, if a comment created by a right-handed reference worker is presented to a left-handed target worker TW, the comment is not helpful to the target worker TW. However, presenting all comments to the target worker TW merely confuses the target worker TW and hinders the target worker TW from knowing which comment is helpful after all. These are not preferable from a viewpoint of learning effectiveness and learning efficiency when the worker learns the predetermined work.

In view of the above, the simulation system 100 according to the present embodiment is provided with a “comment filtering function” for selectively presenting a comment appropriate for the target worker TW.

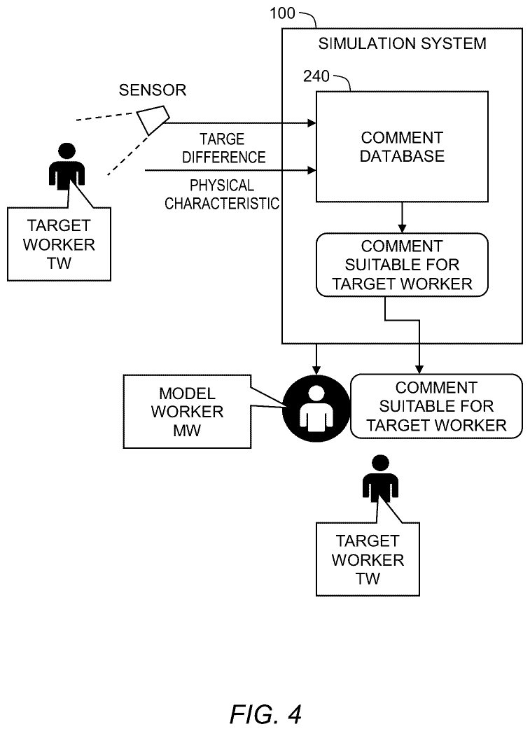

FIG. 4 is a conceptual diagram for explaining the comment filtering function according to the present embodiment. The simulation system 100 acquires information on a characteristic of the target worker TW who carries out the predetermined work. The characteristic of the target worker TW is hereinafter referred to as a “target characteristic.”

A first example of the target characteristic is a difference between the model motion and an actual motion of the target worker TW when carrying out the predetermined work. For example, the actual motion of the target worker TW is an actual motion when the target worker TW carries out the predetermined work in the previous time. The previous actual motion of the target worker TW is obtained from the work record database 220. As another example, the actual motion of the target worker TW may be a real-time motion. The real-time motion of the target worker TW is recognized by the sensor 110 (e.g., the camera). The model motion regarding the predetermined work is obtained from the model motion database 230. The difference between the model motion and the actual motion of the target worker TW when carrying out the predetermined work is hereinafter referred to as a “first difference.” For example, the first difference is an erroneous motion that is not included in the model motion. As another example, the first difference is a delay time of the actual motion of the target worker TW from the model motion. As still another example, the first difference is a distance between a position of a hand of the model worker MW and a position of the hand of the target worker TW.

A second example of the target characteristic is the physical characteristic (e.g., a dominant hand, a hand size, a height, etc.) of the target worker TW. The physical characteristic of the target worker TW is obtained from the worker characteristic database 210.

Subsequently, the simulation system 100 extracts a comment associated with the reference characteristic corresponding to the target characteristic of the target worker TW based on the comment database 240 described above.

In the first example, the reference characteristic of the reference worker includes the reference difference between the model motion and the actual motion of the reference worker when carrying out the predetermined work. The target characteristic of the target worker TW is the first difference between the model motion and the actual motion of the target worker TW when carrying out the predetermined work. The simulation system 100 extracts a comment associated with the reference difference including the first difference, based on the comment database 240. For example, when the first difference is the erroneous motion that is not included in the model motion, the reference difference including the first difference means the reference difference including the same erroneous motion. As another example, when the first difference is the delay time, the reference difference including the first difference means the reference difference equal to or longer than the delay time. As still another example, when the first difference is the distance, the reference difference including the first difference means the reference difference equal to or larger than the distance.

The simulation system 100 may extract a comment associated with the reference difference equivalent to the first difference, based on the comment database 240.

In the second example, the reference characteristic of the reference worker includes the physical characteristic of the reference worker. The target characteristic of the target worker TW includes the physical characteristic of the target worker TW. The simulation system 100 extracts a comment associated with the physical characteristic of the reference worker equivalent to the physical characteristic of the target worker TW, based on the comment database 240. For example, when the target worker TW is left-handed, a comment created by a left-handed reference worker is extracted. The physical characteristic represented by numerical values such as the height is grouped into several groups for each predetermined range. In this case, the physical characteristic equivalent to the physical characteristic of the target worker TW means the physical characteristic of the same group as the target worker TW.

When the target worker TW carries out the predetermined work in the virtual space, the simulation system 100 not only draws the model worker MW in the virtual space but also presents the extracted comment to the target worker TW.

As described above, according to the present embodiment, the comment database 240 is prepared. The comment database 240 indicates the correspondence relationship between the comment created by reference worker (predecessor) regarding the predetermined work and the characteristic of the reference worker. Based on the comment database 240, the comment associated with the characteristic of the reference worker corresponding to the characteristic of the target worker TW is extracted. Then, the extracted comment is selectively presented to the target worker TW.

Not all the comments are indiscriminately presented to the target worker TW, which does not confuse the target worker TW. Meanwhile, an appropriate comment matching the characteristic of the target worker TW is presented to the target worker TW. That is, the target worker TW is able to learn the predetermined work with reference to the appropriate comment matching the characteristic of the target worker TW. For example, the target worker TW is able to refer to a comment created by a reference worker who has made the same mistake as the target worker TW. As another example, the target worker TW is able to refer to a comment created by a reference worker having the same physical characteristic as the target worker TW. Therefore, the learning effectiveness and the learning efficiency of the target worker TW are improved.

What is claimed is:

1. A simulation system for simulating a predetermined work in a virtual space,
the simulation system comprising:
processing circuitry; and
one or more storages storing a comment database, wherein
the comment database indicates a correspondence relationship between a comment created by a reference worker regarding the predetermined work and a characteristic of the reference worker, and
the processing circuitry is configured to:
acquire information on a model motion that serves as a model when carrying out the predetermined work;
acquire information on a characteristic of a target worker carrying out the predetermined work;
extract the comment associated with the characteristic of the reference worker corresponding to the characteristic of the target worker, based on the comment database; and
not only draw a model worker performing the model motion in the virtual space but also present the extracted comment to the target worker, when the target worker carries out the predetermined work in the virtual space.

2. The simulation system according to claim 1, wherein
the characteristic of the reference worker includes a reference difference that is a difference between the model motion and a motion of the reference worker when carrying out the predetermined work,
the characteristic of the target worker includes a first difference that is a difference between the model motion and a motion of the target worker when carrying out the predetermined work, and
the processing circuitry is further configured to extract the comment associated with the reference difference including the first difference, based on the comment database.

3. The simulation system according to claim 2, wherein
the processing circuitry is further configured to extract the comment associated with the reference difference equivalent to the first difference, based on the comment database.

4. The simulation system according to claim 1, wherein
the characteristic of the reference worker includes a physical characteristic of the reference worker,
the characteristic of the target worker includes a physical characteristic of the target worker, and
the processing circuitry is further configured to extract the comment associated with the physical characteristic of the reference worker equivalent to the physical characteristic of the target worker, based on the comment database.

5. A non-transitory computer-readable recording medium storing a simulation program for simulating a predetermined work in a virtual space, wherein
a comment database indicates a correspondence relationship between a comment created by a reference worker regarding the predetermined work and a characteristic of the reference worker, and
the simulation program, when executed by a computer, causing the computer to execute:
acquiring information on a model motion that serves as a model when carrying out the predetermined work;
acquiring information on a characteristic of a target worker carrying out the predetermined work;
extracting the comment associated with the characteristic of the reference worker corresponding to the characteristic of the target worker, based on the comment database; and
not only drawing a model worker performing the model motion in the virtual space but also presenting the extracted comment to the target worker, when the target worker carries out the predetermined work in the virtual space.
